(19) United States
(12) Patent Application Publication
(10) Pub. No.: US 2020/0251341 A1
(43) Pub. Date: Aug. 6, 2020

(54) WET-ETCHING METHOD AND METHOD OF PRODUCING SEMICONDUCTOR DEVICE

(71) Applicant: SHARP KABUSHIKI KAISHA, Sakai City, Osaka (JP)

(72) Inventors: YOHHEI SHINZAKI, Sakai City (JP); HIROAKI OKAJIMA, Sakai City (JP); KAZUKI OGINO, Sakai City (JP)

(73) Assignees: SHARP KABUSHIKI KAISHA, Sakai City, Osaka (JP); SHARP KABUSHIKI KAISHA, Sakai City, Osaka (JP)

(21) Appl. No.: 15/776,064

(22) PCT Filed: Nov. 18, 2016
(86) PCT No.: PCT/JP2016/084251

§ 371 Date: May 14, 2018

(30) Foreign Application Priority Data
Nov. 27, 2015 (JP) 2015-231443

(51) Int. Cl. H01L 21/306; C23F 1/02

(52) U.S. Cl. CPC H01L 21/306; C23F 1/02

(57) ABSTRACT

The invention provides a method of wet-etching a laminate of metal films on a base plate in a target predetermined pattern. The metal films include a naturally oxidized Ti film as a top layer. The method includes a resist forming process of forming a resist film having a shape corresponding to the predetermined pattern on the laminate, a top layer selectively etching process of placing the laminate in contact with a top layer selectively etching solution to mainly etch a portion of the top layer that is not covered by the resist film, and a finishing etching process of placing the laminate in contact with a finishing etching solution to etch all layers including the top layer until a target shape of the laminate is obtained.

### TECHNICAL FIELD

The present invention relates to a wet-etching method and a method of producing a semiconductor device.

### BACKGROUND ART

Various lines such as a gate line and a source line are patterned on a TFT array board included in a liquid crystal panel. The lines of this type are formed by etching a laminate on a glass base plate in a pattern. The laminate includes metal films of two or more kinds.

For example, Patent Document 1 discloses a complex method of wet-etching a laminate including an Al film and a Mo film on a glass base plate. The Al film is etched first by spray etching. Then, the Mo film is etched by paddle etching.

### RELATED ART DOCUMENT

### Patent Document

Patent Document 1: Japanese Unexamined Patent Application Publication No. 2008-277845

### Problem to be Solved by the Invention

The metal film constituting the top layer of the laminate is a Ti film in some cases. In such a case, at least a surface of the Ti film typically undergoes natural oxidation by oxygen or the like in the atmosphere and changes into titanium oxide. It is known that the titanium oxide is etched at an extremely low (slow) etch rate (etch speed) by a chemical solution commonly used in wet-etching. When the laminate including such a titanium oxide in the top layer is wet-etched, the other metal films below the titanium oxide may be preferentially etched before the titanium oxide. In such a case, the laminate has a reverse tapered (inverted trapezoidal) cross-sectional shape. Furthermore, the area of the Ti film that changes into the titanium oxide due to oxidation is not always the same. Thus, the amount of side etching is varied, leading to unevenness in the linewidth of the laminate.

### DISCLOSURE OF THE PRESENT INVENTION

The object of the present invention is to provide a wet-etching method that reliably etches a laminate of metal films including a Ti film as a top layer with less variation in the amount of side etching and with less possibility that the etched laminate will have a reverse tapered cross-sectional, for example, and a method of producing a semiconductor device by the wet-etching method.

### Means for Solving the Problem

The invention provides a method of wet-etching a laminate of metal films on a base plate in a target predetermined pattern. The metal films include a naturally oxidized Ti film as a top layer. The method includes a resist forming process of forming a resist film having a shape corresponding to the predetermined pattern on the laminate, a top layer selectively etching process of placing the laminate in contact with a top layer selectively etching solution to mainly etch a portion of the top layer that is not covered by the resist film, and a finishing etching process of placing the laminate in contact with a finishing chemical solution to etch all layers including the top layer until a target shape of the laminate is obtained.

In a preferable aspect of the above-described wet-etching method, in the top layer selectively etching process, an etch rate (an etch speed) of the top layer to be etched by the top layer selectively etching solution is higher (faster) than an etch rate of the layers located below the top layer.

In a preferable aspect of the above-described wet-etching method, in the finishing etching process, an etch rate (an etch speed) of the layer other than the top layer to be etched by the finishing chemical solution is higher (faster) than an etch rate of the top layer.

In the above-described wet-etching method, the laminate may include, in addition to the top layer, a lowest layer on the base plate, and an intermediate layer between the top layer and the lowest layer. The method may further include, after the top layer selectively etching process, an intermediate layer selectively etching process of placing the laminate in contact with an intermediate layer selectively etching solution to mainly etch a portion of the intermediate layer that is not covered by the resist film.

In a preferable aspect of the above-described wet-etching method, in the intermediate layer selectively etching process, an etch rate (an etch speed) of the intermediate layer to be etched by the intermediate layer selectively etching solution is higher (faster) than an etch rate of the top layer and an etch rate of the lowest layer.

In the above-described wet-etching process, the base plate may include a glass base plate, and the laminate in the predetermined pattern may form a wiring pattern on the base plate.

Furthermore, a method of producing a semiconductor device according to the invention includes performing any one of the above-described wet-etching methods to produce a semiconductor device including the laminate in the predetermined pattern on the base plate.

### Advantageous Effect of the Invention

The present invention provides a method of wet-etching a laminate of metal films including a Ti film as a top layer with less variation in the amount of side etching and with less possibility that the etched laminate will have a reverse tapered cross-sectional shape, for example, and a method of producing a semiconductor device by using the wet-etching method.

### BRIEF DESCRIPTION OF THE DRAWINGS

FIG. 1 is an explanatory view schematically illustrating a cross-sectional configuration of a laminate of metal films to be etched by a wet-etching method according to a first embodiment.

FIG. 2 is an explanatory view schematically illustrating a cross-sectional configuration of the laminate having the top layer selectively etched in a top layer selectively etching process.

FIG. 3 is an explanatory view schematically illustrating a cross-sectional configuration of the laminate etched into a target shape in a finishing etching process.

FIG. 4 is a photograph showing a magnified cross-section of the laminate after the finishing etching process.

FIG. 5 is a photograph showing a magnified cross-section of a laminate of a comparative example after the laminate is etched by a one-component chemical solution.

FIG. 6 is a plan view schematically illustrating positions (twenty-eight positions) where a resist linewidth and a final linewidth of the laminate in a predetermined pattern on a base plate are determined.

FIG. 7 is an explanatory view for a resist linewidth and a final linewidth.

FIG. 8 is a table indicating resist linewidths, final linewidths, and amounts of side etching in the laminate of the first embodiment.

FIG. 9 is a table indicating resist linewidths, final linewidths, and amounts of side etching in the laminate of the comparative example.

FIG. 10 is a graph indicating the amount of side etching in the first embodiment and the amount of side etching in the comparative example in a comparative way.

FIG. 11 an explanatory view schematically illustrating a cross-sectional configuration of a laminate including metal films to be etched by a wet-etching method according to a second embodiment.

FIG. 12 is an explanatory view schematically illustrating a cross-sectional configuration of the laminate having the top layer selectively etched in a top layer selectively etching process according to the second embodiment.

FIG. 13 is an explanatory view schematically illustrating a cross-sectional configuration of the laminate having the top layer selectively etched by an intermediate layer selectively etching process according to the second embodiment.

FIG. 14 is an explanatory view schematically illustrating a cross-sectional configuration of the laminate etched into a target shape in a finishing etching process according to the second embodiment.

FIG. 15 is an explanatory view schematically illustrating a cross-sectional configuration of a laminate including metal films to be etched by a wet-etching method according to a third embodiment.

FIG. 16 is an explanatory view schematically illustrating a cross-sectional configuration of the laminate having the top layer selectively etched by a top layer selectively etching process according to the third embodiment.

FIG. 17 is an explanatory view schematically illustrating a cross-sectional configuration of the laminate etched into a target shape in a finishing etching process according to the third embodiment.

### MODE FOR CARRYING OUT THE INVENTION

### First Embodiment

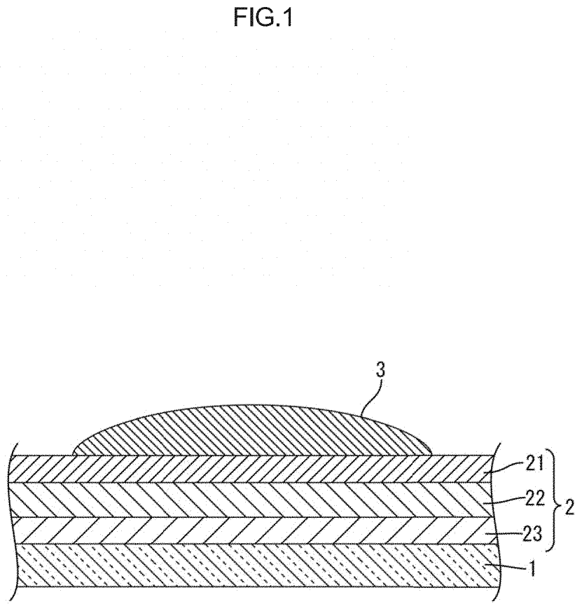

Hereinafter, a first embodiment of the invention is described with reference to FIG. 1 to FIG. 10. In this embodiment, a method of wet-etching a laminate of metal films on a glass base plate in a predetermined pattern is described as an example. FIG. 1 is an explanatory view schematically illustrating a cross-sectional configuration of a laminate of metal films to be etched by the wet-etching method according to a first embodiment. Here, the laminate of metal films to be etched is described first.

As illustrated in FIG. 1, a laminate 2 of metal films, which is an etching target, is formed on a glass base plate (one example of a base plate) 1. The laminate 2 includes at least two layers of metal films. A top layer 21 of the laminate 2 is a Ti film partly or entirely oxidized. In this embodiment, the laminate 2 includes a total of three layers of metal films.

The top layer 21 of the laminate 2 contains titanium oxide, which is oxide of titanium (Ti). The Ti film as the top layer 21 typically undergoes natural oxidation due to oxygen or the like in the atmosphere. Thus, the top layer 21 includes a titanium oxide film, which is a natural oxide film. The titanium oxide film is mainly formed on the front surface of the top layer 21, which readily comes in contact with oxygen or the like in the atmosphere.

An intermediate layer 22 below the top layer 21 is an Al film. Furthermore, a Ti film as a lowest layer 23 is formed below the intermediate layer 22. The Ti film of the lowest layer 23 is formed on the glass base plate (a base plate, a transparent base plate) 1.

The metal films included in the laminate 2 are formed on the base plate 1 by a well-known film forming technique (e.g., physical vapor deposition such as vacuum deposition, sputtering, and ion plating, or chemical vapor deposition) as appropriate. The laminate 2 may be formed over the entire area or a limited area of the surface of the base plate 1.

The top layer (the Ti film, the titanium oxide film) 21, the intermediate layer (the Al film) 22, and the lowest layer (the Ti film) 23, which are metal films included in the laminate 2 the embodiment, have s thickness of about 50 nm, about 300 nm, and about 50 nm, respectively.

In the invention, kinds of metal films included in the laminate, the number of layers of metal films (the number of laminated layers), and kinds of metal or alloy constituting the metal films, for example, may be appropriately determined depending on purposes. Herein, the metal films included in the laminate include an alloy film composed of an alloy.

Before wet-etching of the laminate 2 having the above-described configuration, a photoresist film (one example of a resist film) 3 is formed on the laminate 2 (a resist forming process). The photoresist film 3 is one widely employed in a known photolithography technique and is formed in a predetermined pattern.

### Wet-Etching Method

The wet-etching method in this embodiment uses two kinds of chemical solutions. The wet-etching method includes a top layer selectively etching process and a finishing etching process performed after the top layer selectively etching process.

### Top Layer Selectively Etching Process

In the top layer selectively etching process, the top layer 21 of the laminate 2 is selectively etched by using a top layer selectively etching solution, which is a first chemical solution. As described above, the top layer 21 of the laminate 2 includes a titanium oxide resulting from the natural oxidation of the Ti film. Thus, the top layer 21 including the titanium oxide is likely to be etched by the chemical solution at a fast (high) etch rate compared with the layers other than the top layer 21 (the Al film, the unoxidized Ti film). For example, the top layer 21 including the titanium oxide is likely to be etched at a slow (low) etch rate compared with the other layers (the Al film, the unoxidized Ti film).

To deal with the situation, in the top layer selectively etching process, as a chemical solution for etching the laminate 2 (the top layer selectively etching solution), a chemical solution that etches the titanium oxide (the top layer) at a high (fast) etch rate (etch speed) and etches the layers other than the top layer 21 at a low (slow) etch rate (etch speed) is employed to selectively etch the top layer 21 of the laminate 2.

The top layer selectively etching solution may be a fluorochemical solution that etches titanium oxide at a high (fast) etch rate (etch speed) compared with a common one-component chemical solution, fox example.

Furthermore, in this embodiment, in the top layer selectively etching process, the temperature of the top layer selectively etching solution to be in contact with the laminate 2 and the duration of the contact are adjusted. Specifically described, in the top layer selectively etching process, the temperature of the top layer selectively etching solution to be in contact with the laminate 2 is adjusted to 40° C. and the duration of the contact between the laminate 2 and the top layer selectively etching solution is adjusted to 50 seconds.

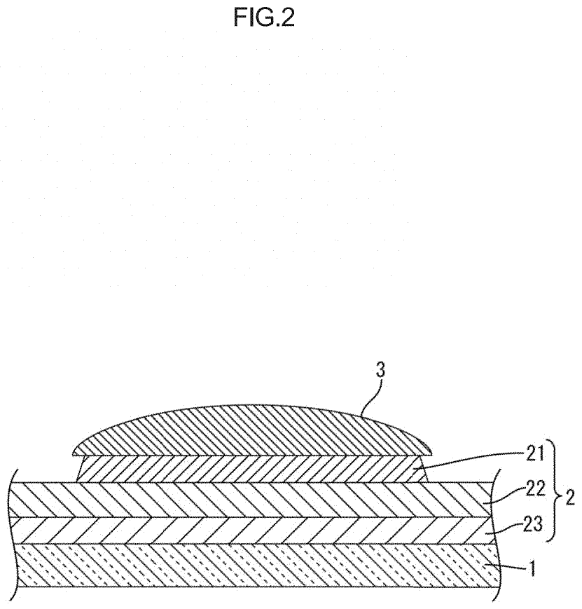

FIG. 2 is an explanatory view schematically illustrating the cross-sectional configuration of the laminate 2 including the top layer 21 selectively etched in the top layer selectively etching process. As illustrated in FIG. 2, in the top layer selectively etching process, the top layer 21 containing the titanium oxide is mainly selectively (preferentially) etched (corroded).

In the top layer selectively etching process, the top layer 21 is etched by the first chemical solution such that the size (the linewidth) of the remaining top layer 21 is slightly larger than the final size of the top layer 21 on the base plate 1. Some types el the top layer selectively etching solutions may etch (corrode) the layers other than the top layer 21 (particularly, the intermediate layer 22 (the Al film) directly below the top layer 21) in the top layer selectively etching process. However, the etching of the layers other than the top layer 21 does not cause a practical problem when the etch rate (the etch speed) of the top layer to be etched by the top layer selectively etching solution is sufficiently higher (faster) than the etch rate (the etch speed) of the layers other than the top layer 21.

The top layer selectively etching process is performed by a known immersion-type or spray-type wet-etching apparatus, for example. A finishing etching process, which is described below, is also performed by a known wet-etching apparatus.

After the top layer selectively etching process, steps such as a cleaning step of cleaning the laminate 2 on the base plate 1 with a cleaning liquid and a drying step of drying the laminate 2 on the base plate 1 may be performed as necessary.

### Finishing Etching Process

In the finishing etching process, all the layers of the laminate 2 including the top layer 21 are etched by using a finishing chemical solution, which is a second chemical solution, until a target shape of the laminate is obtained.

In the finishing etching process, etching is performed on all the layers of the laminate 2 that has been subjected to the top layer selectively etching process using a finishing chemical solution that etches the two layers (the intermediate layer 22 and the lowest layer 23) below the top layer 21 at an etch rate (an etch speed) which is not too high (not too fast) relative to an etch rate (an etch speed) of the top layer 21.

The finishing chemical solution may be a fluorochemical solution that etches the two layers (the intermediate layer 22 and the lowest layer 23) below the top layer 21 at a low etch rate (a low etch speed) compared with a common one-component chemical solution, for example.

Furthermore, in this embodiment, in the finishing etching process, the temperature of the finishing chemical solution to be in contact with the laminate 2 and the duration of the contact are adjusted. Specifically described, in the finishing etching process, the temperature of the finishing chemical solution to be in contact with the laminate 2 is adjusted to 30° C. and the duration of the contact between the laminate 2 and the finishing chemical solution is adjusted to 50 seconds.

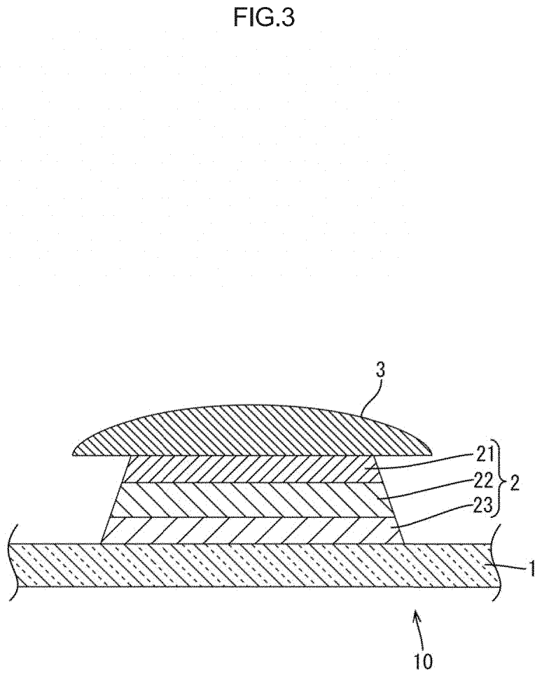

FIG. 3 is an explanatory view schematically illustrating a cross-sectional configuration of the laminate 2 etched into a target shape in the finishing etching process. As illustrated in FIG. 3, all the layers of the laminate 2 are etched in the finishing etching process.

In the finishing etching process, the etch rate (the etch speed) of the two layers of the intermediate layer 22 and the lowest layer 23 to be etched by the finishing chemical solution is higher (faster) than the etch rate (the etch speed) of the top layer 21. However, as described above, the etch rate (the etch speed) of the two layers to be etched by the finishing chemical solution is not too high (not too fast) relative to the etch rate (the etch speed) of the top layer 21. Thus, the finishing chemical solution is unlikely to etch the two layers too much in the finishing etching process.

The laminate 2 after the finishing etching process has a tapered (trapezoidal) cross-sectional shape as illustrated in FIG. 3. The linewidth of the laminate 2 gradually increases from the top layer 21 toward the lowest layer 23.

After the finishing etching process, steps such as a cleaning step of cleaning the laminate 2 on the base plate 1 with a cleaning liquid and a drying step of drying the laminate 2 on the base plate 1 may be performed as necessary.

The laminate 2 in the predetermined pattern is obtained by the above-described wet-etching method. The photoresist film 3 on the laminate 2 is removed appropriately by a known technique after the finishing etching process.

The base plate 1 having the laminate 2 in a predetermined pattern thereon is used as a TFT array base plate (one example of a semiconductor device) 10 of a liquid crystal panel, for example.

As described above, the wet-etching method of this embodiment reliably etches the laminate of the metal layers including the naturally oxidized Ti film as the top layer with less variation in the amount of side etching and with less possibility that the etched laminate will have a reverse tapered cross-sectional shape, for example.

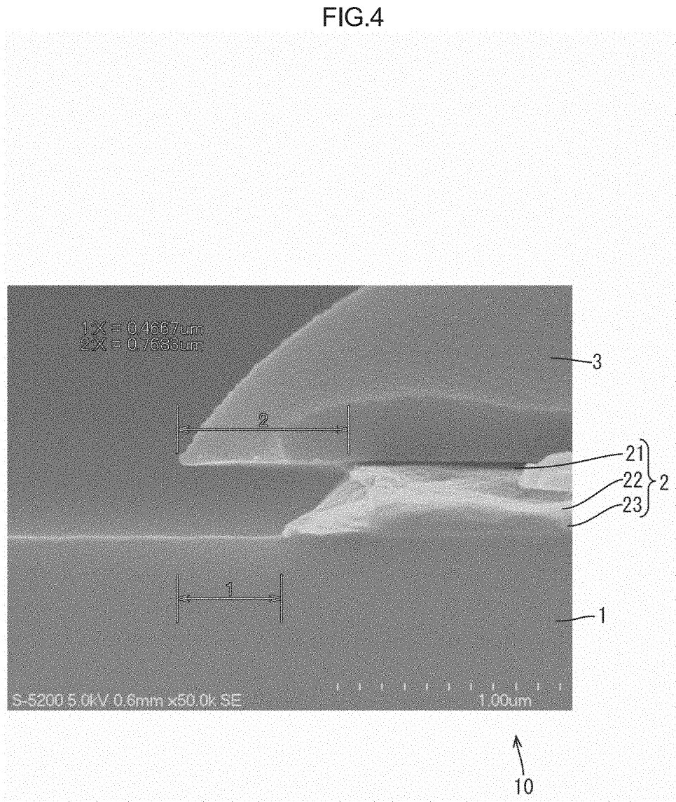

FIG. 4 is a photograph showing a magnified cross-section of the laminate 2 after the finishing etching process. As indicated in FIG. 4, the laminate 2 has a tapered shape.

### Comparative Examples

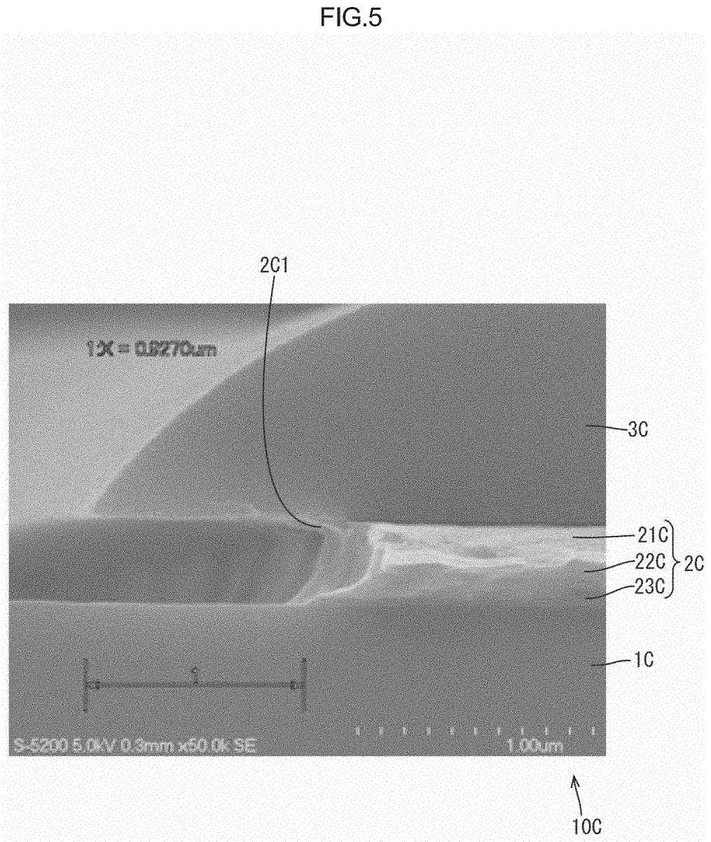

A comparative example is described with reference to FIG. 5. In the comparative example, a laminate 2C having a similar configuration as the laminate 2 in the first embodiment is etched by using a one-component chemical solution. FIG. 5 is a photograph showing a magnified cross-section of the laminate 2C of the comparative example after the laminate 2C is etched by the one-component chemical solution. The laminate 2C in FIG. 5 includes a top layer 21C containing a naturally oxidized Ti film, an intermediate layer 22C including an Al film, and a lowest layer 23C including an unoxidized Ti film, in this order from the top as in the first embodiment. Furthermore, a photoresist film 3C is formed on the laminate 2C as in the first embodiment.

As illustrated in FIG. 5, the laminate 2C that has been etched by the one-component chemical solution has a reverse tapered shape. The top layer 21 including the naturally oxidized Ti layer (titanium oxide) and a portion 2C1 of the Al layer directly below the top layer 21 protrude outwardly like eaves from the other portions below the portion 2C1.

### Comparison Between First Embodiment and Comparative Example

For a board 10 of the first embodiment and a board 10C of the comparative example, resist linewidths L3 end L3C and final linewidths L2 and L2C of the respective etched laminates 2 and 2C are determined at multiple positions (twenty-eight positions). Amounts of side etching are a difference (L3−L2) and a difference (L3C−L2C).

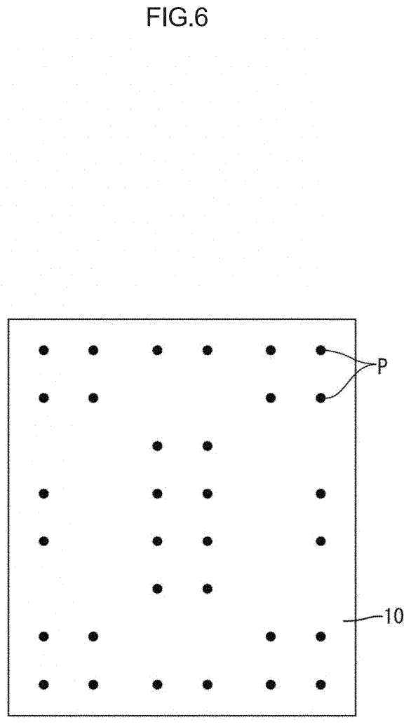

FIG. 6 is a plan view schematically illustrating the positions (twenty-eight position) at which the resist linewidths and the final linewidths of the laminate 2 in the predetermined pattern on the base plate are determined. As illustrated in FIG. 6, the board 10 of the first embodiment has a rectangular shape in plan view. The resist linewidths L3 and the final linewidths L2 of the linear laminate pattern having a predetermine linewidth are determined at the twenty-eight positions mainly around the center and the peripheral portions of the board as illustrated in FIG. 6. Although FIG. 6 illustrates the board 10 of the first embodiment as an example, for the board 10C of the comparative example, the resist linewidths L3C and the final linewidths L2C of the linear laminate pattern having a predetermine linewidth are also determined at the same positions (twenty-eight positions).

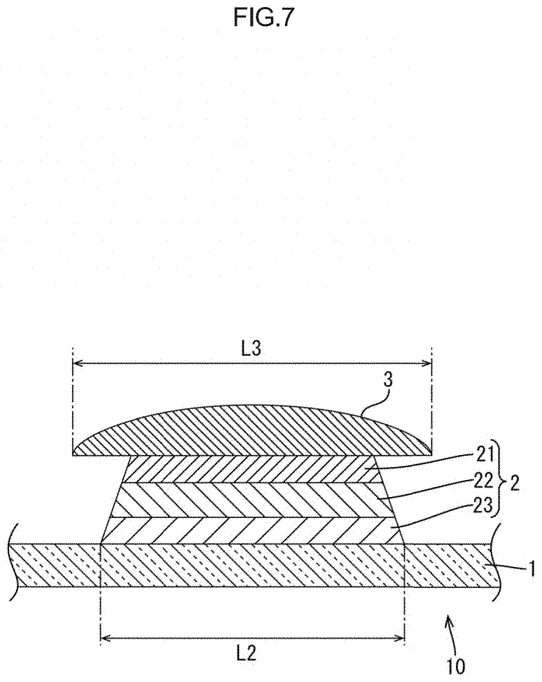

FIG. 7 is an explanatory view for the resist linewidth L3 and the final linewidth L2. As illustrated in FIG. 7, the resist linewidth L3 is a length in the width direction of the linear photoresist film 3 (the length in the lateral direction) and the final linewidth L2 is a length of the lowest portion of the etched linear laminate 2 (the length in the lateral direction). Although FIG. 7 illustrates the board 10 of the first embodiment as an example, the resist linewidth L3 and the final linewidth L2 of the comparative example are determined at the same portions.

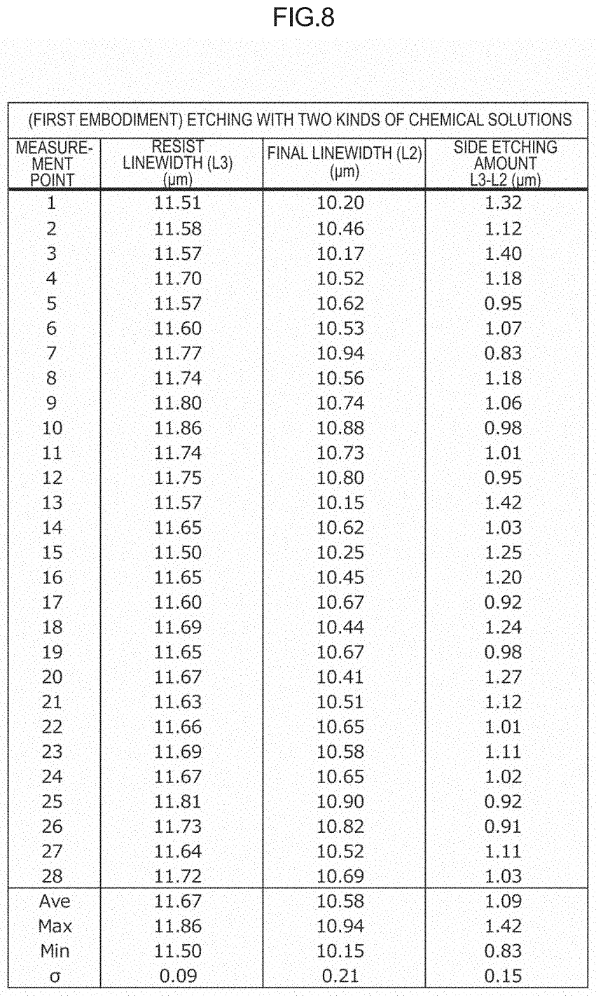

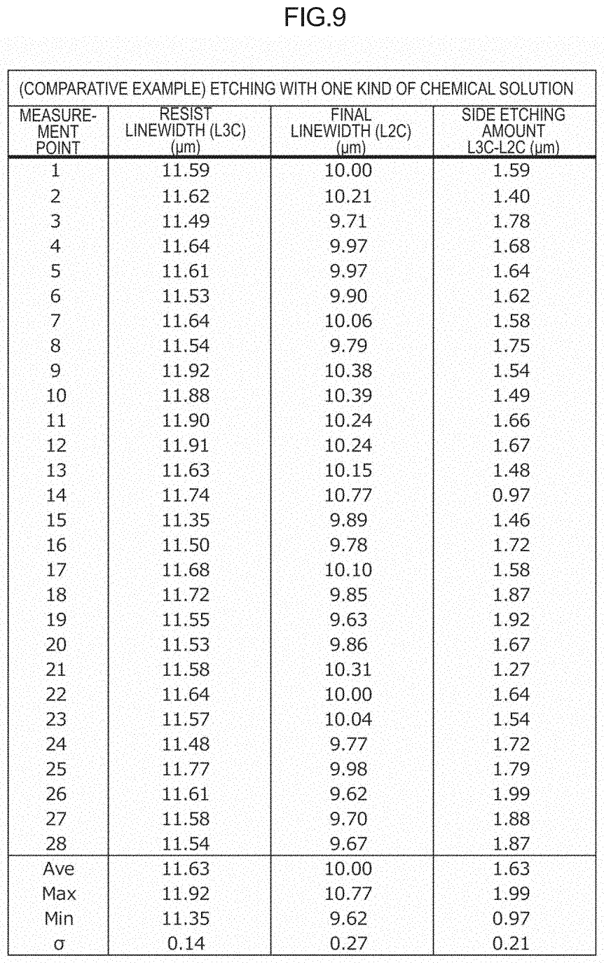

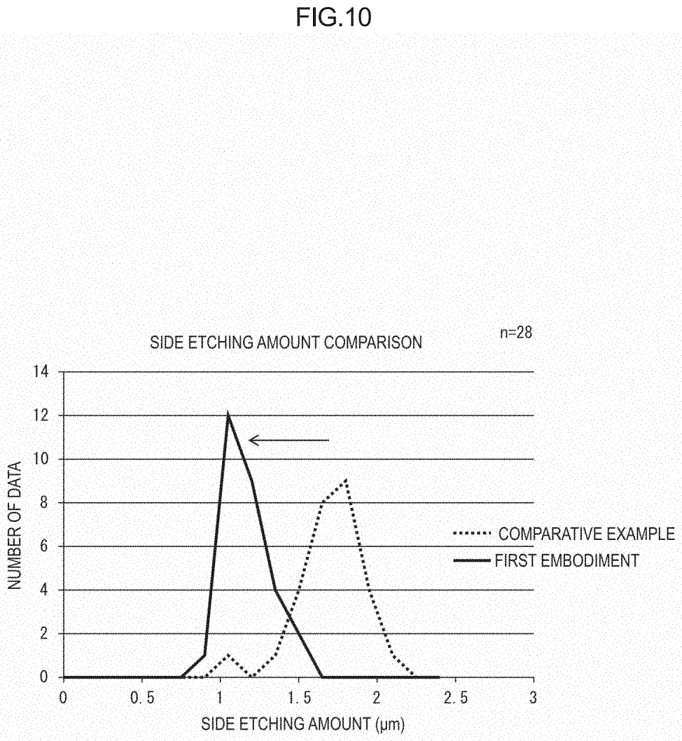

FIG. 8 is a table indicating the resist linewidths L3, the final linewidths L2, and the amounts of side etching of the laminate 2 of the first embodiment. FIG. 9 is a table indicating the resist linewidths L3, the final linewidths L2, and the amounts of side etching of the laminate 2C of the comparative example. FIG. 10 is a graph comparing the amount of side etching in the first embodiment and the amount of side etching in the comparative example.

As indicated in FIG. 10, it is confirmed that the amount of side etching is smaller and less varied in the first embodiment than in the first comparative example.

### Second Embodiment

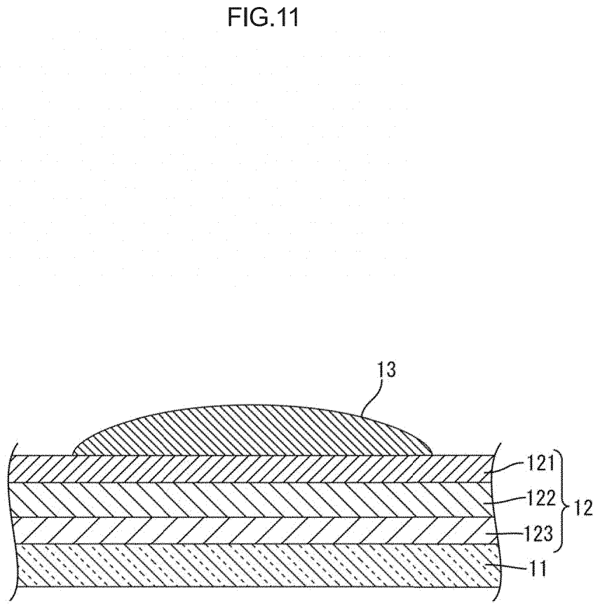

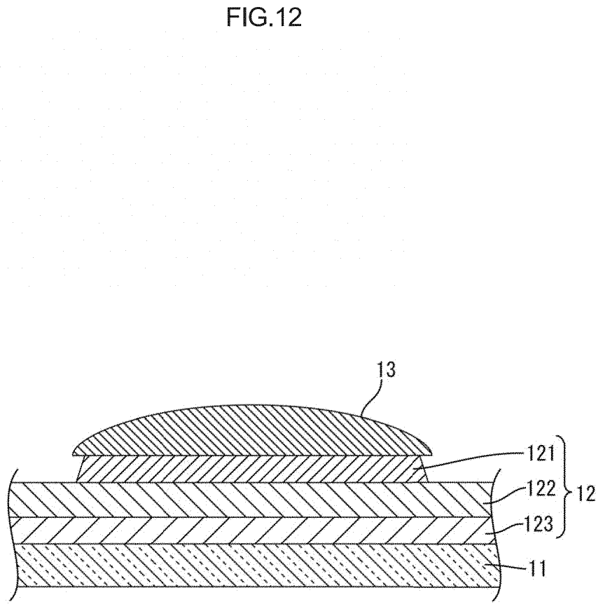

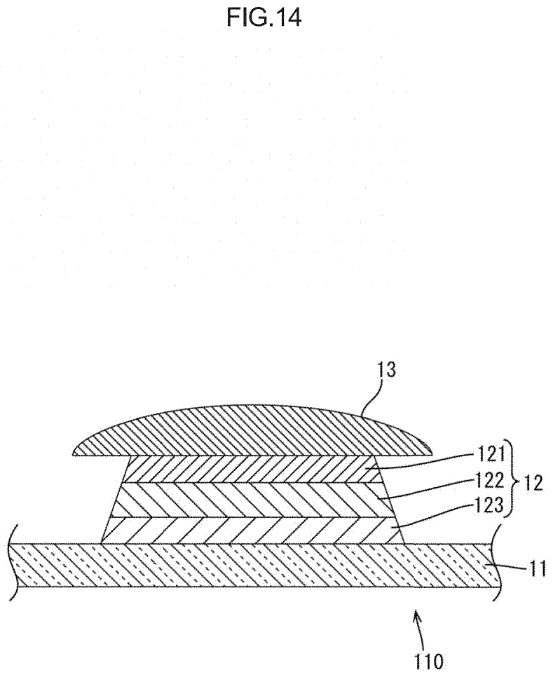

Next, a second embodiment of the invention is described with reference Lo FIG. 12 Lo FIG. 14. FIG. 11 is an explanatory view schematically illustrating a cross-sectional configuration of a laminate 12 including metal films to be etched by a wet-etching method according to the second embodiment. As illustrated in FIG. 11, the laminate 12 including the metal films, which is an etching target, is formed on a glass base plate 11. The laminate 12 has a configuration similar to that of the laminate 2 in the above first embodiment and includes a naturally oxidized Ti film as a top layer 121, an Al film as an intermediate layer 122, and an unoxidized Ti film as a lowest layer 123. On the top layer 121, a photoresist 13 in a predetermined pattern is formed.

Unlike the first embodiment, the wet-etching method of the second embodiment uses three kinds of chemical solutions for etching in a predetermined pattern.

The wet-etching method of the second embodiment includes a top layer selectively etching process, an intermediate layer selectively etching process performed after the top layer selectively etching process, and a finishing etching process performed after the intermediate layer selectively etching process.

### Top layer Selectively Etching Process

In the top layer selectively etching process, the top layer 121 of the laminate 12 is selectively etched by a top layer selectively etching solution, which is a first chemical solution, as in the first embodiment.

FIG. 12 is an explanatory view schematically illustrating a cross-sectional configuration of the laminate 12 including the top layer 121 selectively etched in the top layer selectively etching process according to the second embodiment. As illustrated in FIG. 12, in the top layer selectively etching process, the top layer 121 including titanium oxide is mainly selectively (preferentially) etched (corroded) by the top layer selectively etching solution.

In this embodiment, after the top layer selectively etching process, steps such as a cleaning step of cleaning the laminate 12 on the base plate 11 with a cleaning liquid and a drying step of drying the laminate 12 on the base plate 11 may be performed as necessary.

### Intermediate Layer Selectively Etching Process

In the intermediate layer selectively etching process, the top layer 121 of the laminate 12 is selectively etched by an intermediate layer selectively etching solution, which is a second chemical solution.

In the intermediate layer selectively etching process, the chemical solution (an intermediate layer selectively etching solution) which etches the laminate 12 at an etch rate (an etch speed) which is not too high (not too fast) relative to an etch rate (an etch speed) of the Al film (the intermediate layer) is used.

The intermediate layer selectively etching solution may be a fluorochemical solution that etches the Al film (the intermediate layer) at a low (slow) etch rate (etch speed) compared with a commonly used one-component chemical solution, for example.

Furthermore, in this embodiment, in the intermediate layer selectively etching process, the temperature of the intermediate layer selectively etching solution to be in contact with the laminate 12 and the duration of the contact are adjusted. Specifically described, in the intermediate layer selectively etching process, the temperature of the intermediate layer selectively etching solution to be in contact with the laminate 12 is adjusted to 35° C. and the duration of the contact between the laminate 12 and the intermediate layer selectively etching solution is adjusted to 30 seconds.

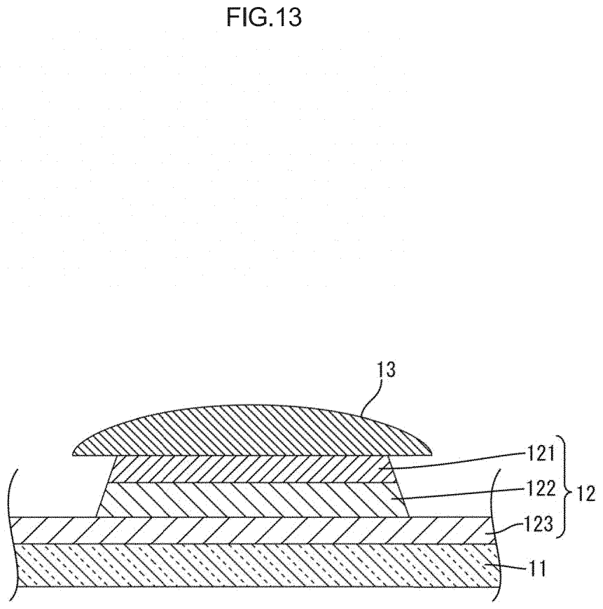

FIG. 13 is an explanatory view schematically illustrating the cross-sectional configuration of the laminate 12 including the top layer 121 selectively etched in the intermediate layer selectively etching process according to the second embodiment. As illustrated in FIG. 13, in the intermediate layer selectively etching process, the intermediate layer 122 including the Al film is mainly selectively (preferentially) etched (corroded).

In the intermediate layer selectively etching process, the intermediate layer 122 is etched by the intermediate layer selectively etching solution such that the size (the linewidth) of the remaining intermediate layer 122 is slightly larger than the final size of the intermediate layer 122 on the base plate 11. Some types of the intermediate layer selectively etching solutions may etch (corrode) the layers other than the intermediate layer 122 (particularly, the lowest layer 123 (the Ti film) directly below the intermediate layer 122) in the intermediate layer selectively etching process. However, the etching of the lowest layer 123 does not cause a practical problem when the etch rate (the etch speed) of the intermediate layer 122 to be etched by the intermediate layer selectively etching solution is sufficiently higher (faster) than the etch tale (the etch speed) of the lowest layer 123.

Furthermore, in the intermediate layer selectively etching process, the intermediate layer selectively etching solution etches to some degrees.

In the intermediate layer selectively etching process, an etch rate (an etch speed) of the intermediate layer 122 to be etched by the intermediate layer selectively etching solution is higher (faster) than an etch rate (an etch speed) of the top layer 121. However, as described above, the intermediate layer selectively etching solution is adjusted such that the etch rate (etch speed) of the intermediate layer 122 is not too high (not too fast) relative to the etch rate (etch speed) of the top layer 121. Thus, the intermediate layer 122 is less likely to be etched too much by the intermediate layer selectively etching solution in the intermediate layer selectively etching process.

The intermediate layer selectively etching process is performed by a known immersion-type or spray-type wet-etching apparatus, for example, as in the etching process of the other embodiment.

After the intermediate layer selectively etching process, such as a cleaning step of cleaning the laminate 12 on the base plate 11 with a cleaning liquid and a drying step of drying the laminate 12 on the base plate 11 may be performed as necessary.

### Finishing Etching Process

In the finishing etching process, all the layers of the laminate 12 including the top layer 121 are etched by using a finishing chemical solution, which is a third chemical solution, until a target shape of the laminate is obtained.

In the finishing etching process, the finishing chemical solution that etches the lowest layer 123 at an etch rate (an etch speed) which is not too high (not too faster) relative to an etch rate (an etch speed) of the top layer 121 and the intermediate layer 122 is used to etch all the layers of the laminate 12.

The finishing chemical solution of this embodiment may be a fluorochemical solution that etches the lowest layer 123 at a low (slow) etch rate (etch speed) compared with a commonly used one-component chemical solution, for example.

Furthermore, in this embodiment, in the finishing etching process, the temperature of the finishing chemical solution to be in contact with the laminate 12 and the duration of the contact are adjusted. Specifically described, in the finishing etching process, the temperature of the finishing chemical solution to be in contact with the laminate 12 is adjusted to 25° C. and the duration of the contact between the laminate 12 and the finishing chemical solution is adjusted to 30 seconds.

FIG. 14 is an explanatory view schematically illustrating a cross-sectional configuration of the laminate 12 etched into a target shape in the finishing etching process of the second embodiment. As illustrated in FIG. 14, all the layers of the laminate 12 are etched in the finishing etching process.

In the finishing etching process, the etch rate (the etch speed) of the lowest layer 123 to be etched by the finishing chemical solution is higher (faster) than the etch rate (the etch speed) of the top layer 121 and the intermediate layer 122. As described above, the etch rate (the etch speed of the lowest layer 123 to be etched by the finishing chemical solution is not too high (not too fast) relative to the etch rate (the etch speed) of the top layer 121 and the intermediate layer 122. Thus, the finishing chemical solution does not etch the top layer 121 and the intermediate layer 122 too much in the finishing etching process.

The laminate 12 after the finishing etching process has a tapered (trapezoidal) cross-sectional shape as illustrated in FIG. 14. The linewidth of the laminate 12 gradually increases from the top layer 121 toward the lowest layer 123.

After the finishing etching process of this embodiment, steps such as a cleaning step of cleaning the laminate 12 on the base plate 11 with a cleaning liquid and a drying step of drying the laminate 12 on the base plate 11 may be performed as necessary.

The laminate 12 in the predetermined pattern is obtained by the above-described wet-etching method. The photoresist film 13 on the laminate 12 is removed appropriately by a known technique after the finishing etching process.

The base plate 11 having the laminate 12 in a predetermined pattern thereon is used as a TFT array board (one example of a semiconductor device) 110 of a liquid crystal panel, for example.

As described above, according to the wet-etching method of this embodiment, the laminate of the metal layers including the naturally oxidized Ti film as the top layer is reliably etched with less variation in the amount of side etching and with less possibility that the cross-sectional shape becomes a reverse tapered shape.

### Third Embodiment

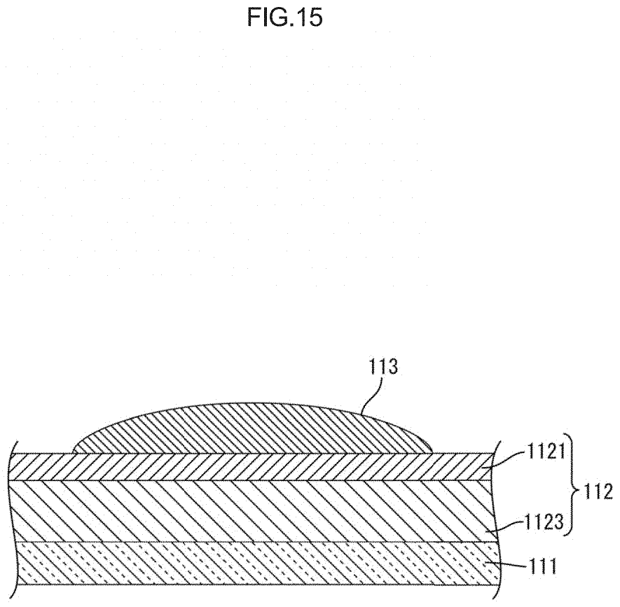

Next, a third embodiment of the invention is described with reference to FIG. 15 to FIG. 17. FIG. 15 is an explanatory view schematically illustrating a cross-sectional configuration of a laminate 112 of metal films to be etched by a wet-etching method according to the third embodiment. As illustrated in FIG. 15, the laminate 112 including the metal films, which is an etching target, is formed on a glass base plate 111. The laminate 112 has a total of two metal films in two layers. The laminate 112 includes a naturally oxidized Ti film as a top layer 1121 and an Al film as a lowest layer 1123. On the top layer 1121, a photoresist 113 in a predetermined pattern is formed. The top layer 1121 and the lowest layer 1123 have a thickness of about 50 nm and about 300 rim, respectively.

The wet-etching method in this embodiment uses two kinds of chemical solutions as in the first embodiment. The wet-etching method includes a top layer selectively etching process and a finishing etching process performed after the top layer selectively etching process.

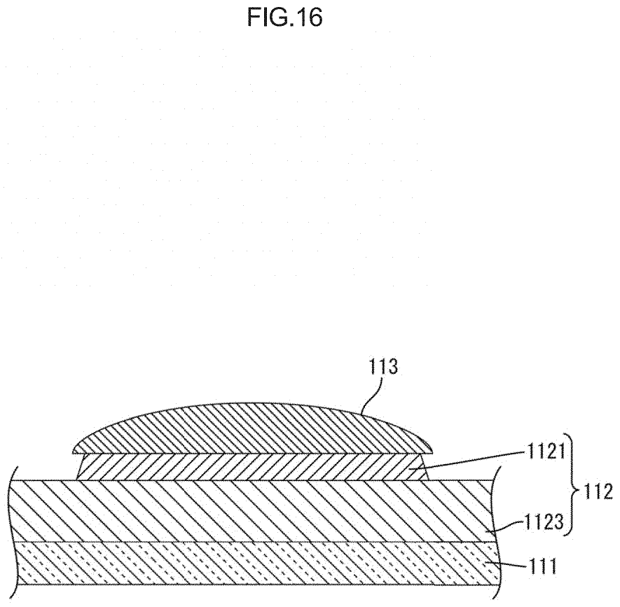

FIG. 16 is an explanatory view schematically illustrating a cross-sectional configuration of the laminate 112 including the top layer selectively etched in the top layer selectively etching process of the third embodiment. In the top layer selectively etching process of this embodiment, the same top layer selectively etching solution as that used in the first embodiment is used. Furthermore, the temperature of the top layer selectively etching solution and the contact duration in the top layer selectively etching process are the same as those in the first embodiment.

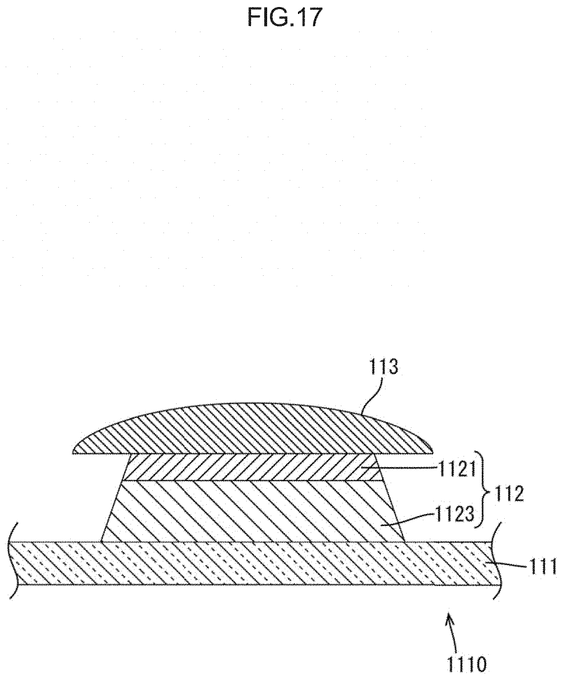

FIG. 17 is an explanatory view schematically illustrating a cross-sectional configuration of the laminate 112 etched into a target shape in the finishing etching process of the third embodiment. In the finishing etching process in this embodiment, the same finishing chemical solution used in the first embodiment is used. The temperature of the finishing chemical solution is adjusted to 35° C. The contact duration of the finishing chemical solution is adjusted to 50 seconds.

As in this embodiment, the two-layered laminate may be wet-etched by using two kinds of chemical solutions. In this embodiment, the laminate 112 that has been subjected to the finishing etching process also has a tapered (trapezoidal) cross-sectional shape as illustrated in FIG. 17. The linewidth of the laminate 112 gradually increases from the top layer 1121 toward the lowest layer 1123.

After the processes in this embodiment, steps such as a cleaning step of cleaning the laminate 112 on the base plate 111 with a cleaning liquid and a drying step of drying the laminate 112 on the base plate 111 may be performed as necessary. The photoresist film 113 on the laminate 112 is appropriately removed by a known technique after the finishing etching process.

As described above, according to the wet-etching method of this embodiment, the laminate of the metal layers including the naturally oxidized Ti film as the top layer is reliably etched with less variation in the amount of side etching and with less possibility that the cross-sectional shape becomes a reverse tapered shape.

The base plate 111 having the laminate 112 in a predetermined pattern thereon is used as a TFT array board (one example of a semiconductor device) 1110 of a liquid crystal panel, for example.

### Other Embodiments

The present invention is not limited to the embodiments described above and illustrated by the drawings. For example, the following embodiments will be included in the technical scope of the present invention.

(1) In the above embodiments, as one example of the semiconductor device, the TFT array board is described. However, the present invention is also applicable to other semiconductor devices.

(2) In the above embodiments, the fluorochemical solution is used as the chemical solution. However, the present invention may employ other kinds of chemical solutions.

### EXPLANATION OF SYMBOLS

1 . . . base plate, 2 . . . laminate, 21 . . . top layer (naturally oxidized Ti film), 22 . . . intermediate layer, 23 . . . lowest layer, 3 . . . photoresist layer, 10 . . . semiconductor device (TFT array board)

1. A method of wet-etching a laminate of metal films on a base plate in a target predetermined pattern, the metal films including a naturally oxidized Ti film as a top layer, the method comprising:
a resist forming process of forming a resist film having a shape corresponding to the predetermined pattern on the laminate:
a top layer selectively etching process of placing the laminate in contact with a top layer selectively etching solution to mainly etch a portion of the top layer that is not covered by the resist film: and
a finishing etching process of placing the laminate in contact with a finishing chemical solution to etch all layers including the lop layer until a target shape of the laminate is obtained.

2. The method according to claim 1, wherein, in the top layer selectively etching process, an etch rate of the top layer to be etched by the top layer selectively etching solution is higher than an etch rate of the layers located below the top layer.

3. The method according to claim 1, wherein in the finishing etching process, an etch rate of the layers other than the top layer to be etched by the finishing chemical solution is higher than an etch rate of the top layer.

4. The method according to claim 1, wherein the laminate includes, in addition to the top layer, a lowest layer on the base plate, and an intermediate layer between the top layer and the lowest layer, and
the method further comprises, after the top layer selectively etching process, an intermediate layer selectively etching process of placing the laminate in contact with an intermediate layer selectively etching solution to mainly etch a portion of the intermediate layer that is not covered by the resist film.

5. The method according to claim 4, wherein, in the intermediate layer selectively etching process, an etch rate of the intermediate layer to be etched by the intermediate layer selectively etching solution is higher than an etch rate of the top layer and an etch rate of the lowest layer.

6. The method according to claim 1, wherein the base plate includes a glass base plate, and
the laminate in the predetermined pattern forms a wiring pattern on the base plate.

7. A method of producing a semiconductor device comprising performing the method according to claim 1 to produce a semiconductor device including the laminate in the predetermined pattern on the base plate.
